(19) United States
(12) Patent Application Publication
(10) Pub. No.: US 2013/0202849 A1
(43) Pub. Date: Aug. 8, 2013

(54) POLYCRYSTALLINE DIAMOND FOR DRAWING DIES AND METHOD FOR FABRICATING THE SAME

(71) Applicant: Korea Institute of Science and Technology, Seoul (KR)

(72) Inventors: Young Joon BAIK, Seoul (KR); Jong Keuk PARK, Seoul (KR); Wook Seong LEE, Seoul (KR)

(73) Assignee: KOREA INSTITUTE OF SCIENCE AND TECHNOLOGY, Seoul (KR)

(21) Appl. No.: 13/759,730

(22) Filed: Feb. 5, 2013

(30) Foreign Application Priority Data
Feb. 6, 2012 (KR) 10-2012-0011589

(51) Int. Cl. C23C 16/30

(52) U.S. Cl. CPC C23C 16/30
USPC 428/141; 427/255.28

(57) ABSTRACT

Provided are polycrystalline diamond for drawing dies, which inhibits preferential wear along specific lattice planes while ensuring wear resistance by controlling the shape and orientation of the grains forming polycrystalline diamond solid, and a method for fabricating the same. The polycrystalline diamond for drawing dies includes a section of diamond having an isotropic granular structure or a radially oriented texture, or has a stacked structure including an isotropic granular layer and a radial texture layer alternately in multiple layers.

### CROSS-REFERENCE TO RELATED APPLICATION

This application claims priority to Korean Patent Application No. 10-2012-0011589, filed on Feb. 6, 2012, and all the benefits accruing therefrom under 35 U.S.C. §119, the contents of which in its entirety are herein incorporated by reference.

### BACKGROUND

1. Field

The present disclosure relates to polycrystalline diamond for drawing dies and a method for fabricating the same. More particularly, the present disclosure relates to polycrystalline diamond for drawing dies, which inhibits uneven wear while ensuring wear resistance by controlling the shape and orientation of the grains forming polycrystalline diamond, and a method for fabricating the same.

2. Description of the Related Art

A drawing die is a system that draws a metal such as copper, gold or the like by using a material having high hardness to produce ultrafine metal wires. Materials applicable to a drawing die include carbide, ceramics, natural diamond, ultrahigh-pressure synthesized single crystal diamond, sintered polycrystalline diamond, or the like. Among those, in the case of drawing of ultrafine wires having a diameter of several tens of micrometers or less, natural diamond or ultrahigh-pressure synthesized single crystal diamond is used. However, when using single crystal diamond, wear resistance varies with crystal surfaces, and thus a drawing hole may not maintain a circular shape upon wire drawing, resulting in uneven wear. As a result, wear resistance shows significant dependence on lattice orientation so that metal wires passed through the hole are problematic, for example, in that the cross-sections of the metal wires may not maintain a circular shape.

In addition, when drawing metal wires having high strength or hardness, excessive stress is applied to a drawing die, thereby causing cracks in the material, and then such cracks propagate easily along crystal cleavage plane orientation to shorten the lifespan of the drawing die. For this reason, there has been suggested use of polycrystalline diamond.

In general, polycrystalline diamond for use in industrial applications is fabricated by an ultrahigh-pressure/temperature process (a pressure of 5 GPa or more and a temperature of 1300° C. or higher). In addition, a Co-, Ni- or Fe-based metal or ceramic (e.g. SiC) is used for such polycrystalline diamond as a sintering aid or binder in an amount of about 10%. The presence of such a sintering aid makes it difficult to make a precise surface of wire during processing. Moreover, voids may be generated upon wire drawing at the site where a sintering aid has been removed initially, thereby limiting use in drawing of ultrafine wires. Recently, there has been suggested a method for fabricating polycrystalline diamond for use in drawing dies by an ultrahigh-pressure/temperature process without any sintering aid from Korean Laid-Open Patent Publication No. 2009-109110. However, the method has disadvantages in that it is difficult to synthesize single-phase polycrystalline diamond into a large size suitable for a drawing die without any sintering aid, as well as to control microstructures for preventing wear or cleavage and cracking in a drawing die.

Meanwhile, unlike ultrahigh-pressure synthesis, diamond obtained by Chemical Vapor Deposition (CVD) in which diamond is synthesized by the reaction of a mixed gas containing hydrogen and hydrocarbon is 100% diamond containing no other impurities or phases, and has a polycrystalline structure. Thus, it is expected that CVD diamond solves the above-mentioned problems. There has been attempt to use a carbide or ceramic die whose surface is coated with CVD diamond so that the advantages of CVD diamond are applied (Korean Patent Publication No. 104850). However, application of diamond coating with a thickness of 10-80 μm as disclosed in Korean Patent Publication No. 104850 cannot provide sufficient adhesion to cause separation of diamond film upon wire drawing, leading to limitation in practical use.

As another attempt, a thick film of CVD diamond is synthesized and cut into a desired shape so that it may be used for applications where conventional single crystal diamond is used. A thick film of CVD diamond has a texture in which the grains forming the thick film are aligned along the thickness direction and an assembled texture in which the columnar grains provide a specific lattice orientation. Due to the specific orientation characteristics of a textured film, a thick film of CVD diamond has structural problems in that it has weak grain boundaries to cause cracks or preferential wear and such cracks propagate along the longitudinal direction of the columnar grains, when applied to a drawing die.

### REFERENCES OF THE RELATED ART

### Patent Document

(Patent Document 1) Korean Patent Publication No. 10-2009-0109110
(Patent Document 2) Korean Patent No. 10-104850

### SUMMARY

The present disclosure is directed to providing polycrystalline diamond for drawing dies, which inhibits uneven wear while ensuring wear resistance by controlling the shape and orientation of the grains forming polycrystalline diamond, and a method for fabricating the same.

In one aspect, there is provided polycrystalline diamond for drawing dies which includes a cross-section of diamond crystalline body having an isotropic equiaxed grains or a radial texture consisted of columnar grains.

According to an embodiment, the diamond film, consisted of isotropic equiaxed grains, is formed on a substrate through a CVD) process using hydrogen (H₂) and methane (CH₄) are used as precursors, wherein methane is present at 4-5 vol % in the mixed gas of hydrogen (H₂) and methane (CH₄). The isotropic equiaxed diamond grains have a sub-micrometer size. During the CVD process, the substrate may be maintained at a temperature of 700-950° C.

According to another embodiment, the radial columnar textured diamond is formed on a substrate through a CVD process using hydrogen (H₂) and methane (CH₄) are used as precursors, wherein methane is present at 1-2 vol % in the mixed gas of hydrogen (H₂) and methane (CH₄). In the CVD process, the substrate may be controlled to a temperature of 700-950° C.

According to still another embodiment, radial columnar textured diamond solid may be grown by using a CVD process, while diamond powder is randomly and individually distributed on the substrate, or radial columnar textured diamond solid may be grown by a CVD process, where the columnar diamond grains grow propagating from the individual diamond powder radially.

In another aspect, there is provided polycrystalline diamond solid for drawing dies which is stacked alternately with an isotropic equiaxed grain layer and a radially textured layer of columnar grains elongated in a radial direction.

In still another aspect, there is provided a method for fabricating diamond for drawing dies, including forming polycrystalline diamond film having an isotropic equiaxed grains on a substrate by a CVD process using hydrogen (H₂) and methane (CH₄) as precursors, wherein methane is present at 4-5 vol % in the mixed gas of hydrogen (H₂) and methane (CH₄).

In still another aspect, there is provided a method for fabricating diamond for drawing dies, including forming polycrystalline diamond film having radial columnar grains on a substrate by a CVD process using hydrogen (H₂) and methane (CH₄) as precursors, wherein methane is present at 1-2 vol % in the mixed gas of hydrogen (H₂) and methane (CH₄).

In yet another aspect, there is provided a method for fabricating diamond for drawing dies, including stacking a layer of isotropic equiaxed grains and a layer of radial columnar grains alternately into multiple layers on a substrate by a CVD process using hydrogen (H₂) and methane (CH₄) as precursors, wherein methane is present at 4-5 vol % in the mixed gas of hydrogen (H₂) and methane (CH₄) upon forming the isotropic equiaxed diamond grains layers, while methane is present at 1-2 vol % in the mixed gas of hydrogen (H₂) and methane (CH₄) upon forming the radial columnar textured diamond grains layers.

The polycrystalline diamond for drawing dies and method for fabricating the same disclosed herein provide the following effects.

Since the polycrystalline diamond film has either an isotropic equiaxed grains layer or a radial columnar grains layer or a combination thereof, it is possible to inhibit uneven wear of diamond, thereby providing uniform wire drawing.

In addition, since an isotropic equiaxed grains layer and a radial columnar grains textured layer are fabricated by controlling the processing temperature and precursor gas composition while carrying out a CVD process, it is possible to control the process with ease.

### BRIEF DESCRIPTION OF THE DRAWINGS

The above and other aspects, features and advantages of the disclosed exemplary embodiments will be more apparent from the following detailed description taken in conjunction with the accompanying drawings in which:

FIG. 1 is a schematic view illustrating the columnar texture of diamond obtained according to the related art;

FIG. 2 is a schematic view illustrating diamond films consisted of isotropic equiaxed grains according to an embodiment;

FIG. 3 is a schematic view illustrating the radially textured diamond solid of columnar grains according to another embodiment;

FIG. 4 is a schematic view illustrating polycrystalline diamond solid including alternately stacked isotropic equiaxed grains layers and radial columnar grains textured layers according to still another embodiment;

FIG. 5 is a surface Scanning Electron Microscopy (SEM) image of the isotropic equiaxed grains according to an embodiment; and

FIG. 6 is a sectional Transmission Electron Microscopy (TEM) image of the isotropic equiaxed grains according to an embodiment.

### DETAILED DESCRIPTION

Exemplary embodiments now will be described more fully hereinafter with reference to the accompanying drawings, in which exemplary embodiments are shown.

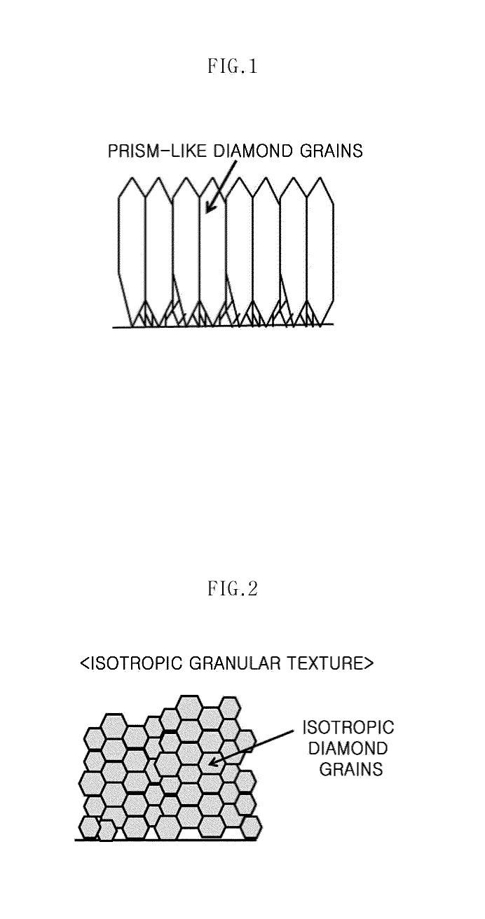

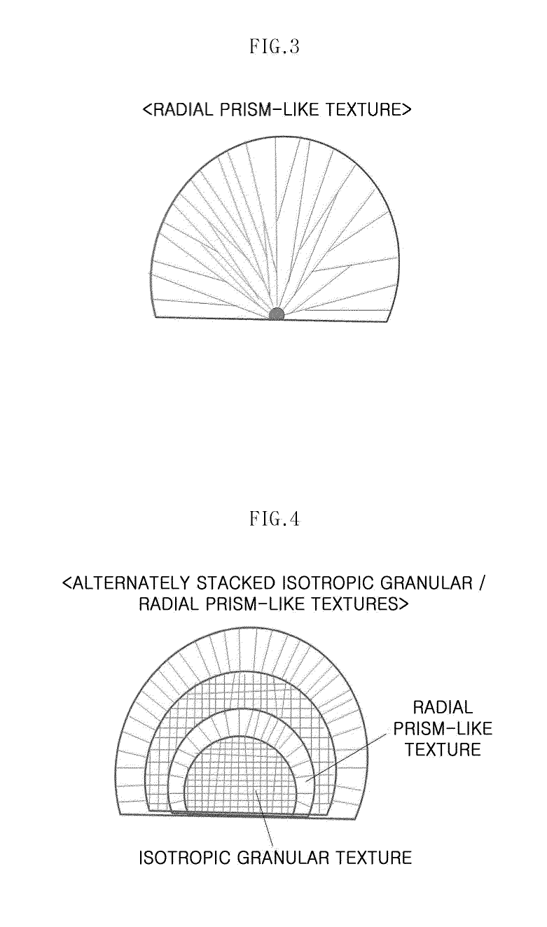

According to some embodiments of the present disclosure, polycrystalline diamond is synthesized by using CVD process, wherein the proportion of methane gas is controlled at a predetermined temperature to provide polycrystalline diamond grains with an isotropic equiaxial shape (see FIG. 2, a radially oriented columnar shape (see FIG. 3), or with a stacked structure having alternately stacked isotropic equiaxed grains layers and radial columnar grains textured layers (see FIG. 4). When polycrystalline diamond solid is provided with columnar grains grown with their elongation in a radial alignment or randomly oriented isotropic equiaxed grains, diamond crystal grains in the solid are not grown having a specific crystal direction parallel to the hole axis through which wire is drawn, and thus are expected to undergo less uneven wear during use in a wire drawing die due to an anisotropy of wear property according to the lattice orientation. Although the polycrystalline diamond solid obtained according to the related art has a merit of isotropic wear due to random orientation of columnar grains normal to the growth direction, the crack can easily propagate along the growth direction through cleavage plane inside the columnar grains due to the lack of grain boundaries along the growth direction. This is a critical disadvantage of the polycrystalline diamond grown as shown in FIG. 1. In the CVD process according to the present disclosure, hydrogen (H₂) and methane (CH₄) are used as precursors and the methane content is controlled within a range of 1-5 vol % in the mixed gas of hydrogen with methane. As the methane content decreases (particularly, when the methane content is 1-2 vol %), grains are grown in a radial columnar texture. As the methane content increases (particularly, when the methane content is 4-5 vol %), grains are grown in an isotropic equiaxed shape. When the methane content is less than 1 vol %, no diamond grains are grown. When the methane content is greater than 5 vol %, the deposited film contains large portion of graphite instead of diamond due to excessive supersaturation.

The deposited solid consisted of isotropic equiaxed grains is referred to as a solid in which sub-micrometer sized granular diamond grains are grown equiaxially (see FIG. 2). A radial columnar grain texture is referred to as a texture in which elongated columnar diamond grains are grown radially on the surface of a localized point substrate such as diamond particles (see FIG. 3). In addition to the isotropic granular structure, the radial columnar texture includes elongated grains grown along a radial direction has also no specific orientation along a hole axis of drawing dies if the hole is made along the direction normal to the substrate surface shown in FIG. 3.

Two methods may be used to grow polycrystalline diamond in the form of a radial columnar grain texture. To grow polycrystalline diamond having a general columnar texture, pretreatment is required to subject the surface of a substrate to uniform heterogeneous nucleation. The pretreatment is performed by scratching the surface of a substrate with ultrafine diamond powders. When diamond is deposited on the surface of a substrate subjected to such uniform scratching, the columnar grains can be grown only along the direction of the substrate surface normal after all the grains on the surface are impinged one another and thus form a one-dimensional texture having its orientation defined along the substrate surface normal.

The method for forming a radial columnar texture disclosed herein is based on the above-described phenomenon. (Here we define a radial texture is the solid consisted of grains which are elongated along the radial direction, comparing with the one dimensional texture mentioned above.) One method is the usage of small piece of substrate such as Si whose surface is pretreated by the ultrafine diamond powders for diamond nucleation. The size of the substrate is small enough to grow columnar diamond grains radially from the substrate which plays a role of a starting point of the growth of the radially growing columnar diamond grains. The preferable size of the substrate is typically less than one tenth of the final size of the grown diamond solid. Such local presence of the starting point of diamond solid growth on the substrate surface induces the radially textured film structure so that the lattice orientation of diamond grains along the substrate surface normal is random as shown in FIG. 3.

The other method is carrying out a CVD process on diamond powder distributed separately on a substrate holder. At the portions other than the portions where diamond powder exists, diamond deposition is hardly generated and occurs only on the diamond powder, thereby providing the same effect as the method described hereinabove.

Meanwhile, when carrying out the CVD process disclosed herein, the substrate is controlled to a temperature of 700-950° C. When the temperature of a substrate is lower than 700° C., no diamond crystal growth or very slow diamond deposition is accomplished. When the temperature of a substrate is higher than 950° C., the growing grains contain high percentage of the graphite phase. In addition, according to some embodiments, polycrystalline diamond is grown on a substrate. The substrate holder used here, where the either the small pieces of surface treated Si or diamond powders are placed, should be a material having very dissimilar lattice parameter and very little chemical affinity with diamond so that diamond nucleation can hardly occur on it. For example, a silicon substrate may be used. Without any surface treatment, almost no nucleation of diamond occur.

Particular examples of the CVD process applicable to the present disclosure include hot filament chemical vapor deposition (HFCVD), plasma enhanced chemical vapor deposition (PECVD), or the like.

The examples will now be described to illustrate the method for polycrystalline diamond for drawing dies disclosed herein in detail and to determine the characteristics of the resultant diamond. The following examples are for illustrative purposes only and not intended to limit the scope of the present disclosure.

### EXAMPLE 1

### Polycrystalline Diamond Solid Preparation Having Isotropic Equiaxed Diamond Grains

A hot filament CVD (HFCVD) process is used to grow polycrystalline diamond on a silicon substrate. Hydrogen (H₂) and methane (CH₄) are used as precursors, wherein methane content is 5 vol %. In addition, the substrate is maintained at a temperature of 700° C. and the pressure inside a chamber is set to 40 torr.

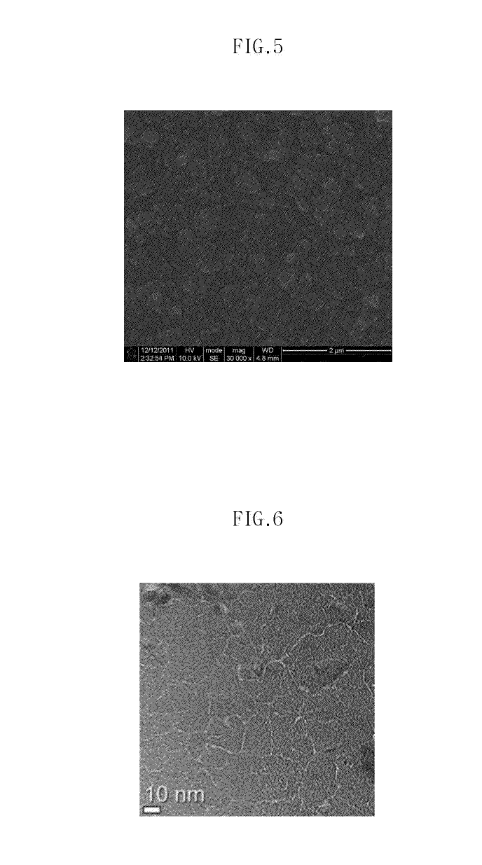

After the growth of crystals, it can be seen from FIG. 5 and FIG. 6 that granular grains having a size of several tens of nanometers (nm) are grown equiaxially. No phase other than diamond exists among the grains. After analyzing the grains by X-ray Diffractometry (XRD), it can be seen that the grains are randomly oriented.

### EXAMPLE 2

### Preparation of Radial Textured Polycrystalline Diamond

While diamond grains having a size of several hundreds of micrometers (μm) are distributed randomly on a silicon substrate, a HFCVD process is carried out. The same conditions of temperature and pressure as Example 1 are used in this Example, except that methane content is set to 1 vol % during the process.

After the growth of crystals, grain growth is accomplished around the diamond grains distributed on the surface, thereby providing a radial columnar texture finally.

### EXAMPLE 3

### Alternate Growth of Radially Textured Layer and Isotropic Equiaxed Granular Layer

The process of Example 2 and that of Example 1 are repeated to stack polycrystalline diamond layers having a radially textured with columnar polycrystalline diamond layers and an isotropic equiaxed granular layer alternately in multiple layers. The process of Example 2 and that of Example 1 are carried out within a periodic time interval controlled to between 30 minutes and several hours.

It can be seen that a radial texture is formed when methane content is 1 vol %, while an isotropic granular layer is formed when methane content is 5 vol %. As a result, it is possible to obtain a layered structure including radially textured layers and isotropic granular layers. In addition, it is possible to control the thickness of such a layered structure by controlling the processing time of Examples 2 and that of Example 1.

While the exemplary embodiments have been shown and described, it will be understood by those skilled in the art that various changes in form and details may be made thereto without departing from the spirit and scope of the present disclosure as defined by the appended claims.

What is claimed is:

1. Polycrystalline diamond for drawing dies, comprising a section of diamond crystalline texture having radially elongated columnar grains.

2. Polycrystalline diamond for drawing dies, comprising an isotropic equiaxed grain layer and a radially elongated columnar grain textured layer, stacked alternately in multiple layers.

3. A method for fabricating polycrystalline diamond for drawing dies, comprising carrying out a chemical vapor deposition (CVD) process using hydrogen (H₂) and methane (CH₄) as precursors to form polycrystalline diamond having isotropic equiaxed grains on a substrate, wherein methane is present at 4-5 vol % in the mixed gas of hydrogen (H₂) and methane (CH₄).

4. A method for fabricating polycrystalline diamond for drawing dies, comprising carrying out a chemical vapor deposition (CVD) process using hydrogen (H₂) and methane (CH₄) as precursors to form polycrystalline diamond solid having radially elongated columnar grains on a substrate, wherein methane is present at 1-2 vol % in the mixed gas of hydrogen (H₂) and methane (CH₄).

5. The method for fabricating polycrystalline diamond for drawing dies according to claim 3, wherein the substrate has a temperature of 700-950° C.

6. The method for fabricating polycrystalline diamond for drawing dies according to claim 4, wherein the substrate has a temperature of 700-950° C.

7. The method for fabricating polycrystalline diamond for drawing dies according to claim 4, wherein the diamond solid having the radially elongated columnar grains is grown by using a chemical vapor deposition (CVD) process, while diamond powder is distributed randomly and individually on the substrate.

8. The method for fabricating polycrystalline diamond for drawing dies according to claim 4, wherein the diamond solid having the radially elongated columnar grains is grown by using a chemical vapor deposition (CVD) process, while the substrate surface is subjected to specific pretreatment for diamond nucleation.

9. A method for fabricating diamond for drawing dies, comprising:
stacking isotropic equiaxed grains diamond crystal layers and radially elongated columnar grains textured diamond crystal layers alternately in multiple layers on a substrate by a chemical vapor deposition (CVD) process using hydrogen (H₂) and methane (CH₄) as precursors,
wherein methane is present at 4-5 vol % in the mixed gas of hydrogen (H₂) and methane (CH₄) upon forming the isotropic equiaxed grains diamond crystal layers, while methane is present at 1-2 vol % in the mixed gas of hydrogen (H₂) and methane (CH₄) upon forming the radially elongated columnar grains textured diamond crystal layers.

10. The method for fabricating polycrystalline diamond for drawing dies according to claim 9, wherein the substrate has a temperature of 700-950° C.
